(19) United States
(12) Patent Application Publication
(10) Pub. No.: US 2025/0246253 A1
(43) Pub. Date: Jul. 31, 2025

(54) MEMORY DEVICE, INTEGRATED CIRCUIT AND OPERATING METHOD OF MEMORY DEVICE

(71) Applicant: Ipcell Corporation Limited, Hong Kong (HK)

(72) Inventor: Te-Hsun HSU, Hsinchu County (TW)

(21) Appl. No.: 18/951,548

(22) Filed: Nov. 18, 2024

(30) Foreign Application Priority Data
Jan. 31, 2024 (CN) 202410137306.5

(51) Int. Cl. G11C 17/16; G11C 17/18; H10B 20/25

(52) U.S. Cl. CPC G11C 17/16; G11C 17/18; H10B 20/25

(57) ABSTRACT

A memory device is provided. The memory device includes an one-time programmable non-volatile memory cell having an antifuse element, a first transistor, a second transistor and a third transistor. The antifuse element has a first terminal coupled to a program line. The first transistor is coupled between a second terminal of the antifuse element and a source line. The first transistor is turned on to form a write path to the antifuse element. A control terminal of the second transistor is coupled to a second terminal of the antifuse element. The third transistor is turned on to form a read path to the antifuse element. A first terminal of the third transistor is coupled to the source line and a second terminal of the third transistor is coupled to a first terminal of the second transistor.

CROSS-REFERENCE TO RELATED APPLICATION

This application claims priority to China Application Serial Number 202410137306.5, filed Jan. 31, 2024, which is herein incorporated by reference in its entirety.

### BACKGROUND

### Description of Related Art

A one-time programmable (OTP) non-volatile memory is a non-volatile memory that can only be programmed once. The data written to the OTP non-volatile memory cannot be erased and can be retained without power supplied to the OTP non-volatile memory. The OTP non-volatile memory is applied for storage of firmware, intrinsic feature and manufacture information of integration circuit, etc.

An antifuse is an implementation of the OTP non-volatile memory. The structure of the antifuse includes two conducting plates arranged in parallel with a dielectric medium between them. A high bias voltage is applied to the conducting plates making the dielectric medium broke down to program the antifuse. On account of factors like manufacturing defect, significant difference of severity of the dielectric breakdown may exist between individual antifuses. For example, after the dielectric medium broke down, oxide recovery occurs to the dielectric medium of some antifuses. These antifuses enter a state of soft breakdown and have smaller leakage current.

In some approaches, the program path and the read path of the antifuse are the same. In such condition, the difference of severity of the dielectric breakdown may cause significant difference of read currents between individual memory devices, which reduces performance of the memory devices.

### SUMMARY

One aspect of the present disclosure is to provide a memory device comprising a one-time programmable non-volatile memory (OTP NVM) cell that comprises an antifuse element, a first transistor, a second transistor and a third transistor. The antifuse element has a first terminal coupled to a program line. The first transistor is coupled between a second terminal of the antifuse element and a source line. The first transistor is turned on to form a write path to the antifuse element. A control terminal of the second transistor is coupled to the second terminal of the antifuse element. A third transistor is turned on to form a read path to the antifuse element. A first terminal of the third transistor is coupled to the source line and a second terminal of the third transistor is coupled to a first terminal of the second transistor.

In some embodiments, a control terminal of the first transistor is coupled to a write word line. A second terminal of the second transistor is coupled to a bit line and a control terminal of the third transistor is coupled to a read word line. In a write operation, the write word line and the program line have a first voltage, and the read word line and the bit line have a ground voltage.

In some embodiments, in a read operation, the write word line has the ground voltage, the program line and the read word line have a second voltage smaller than the first voltage, and the bit line has a third voltage smaller than the second voltage.

In some embodiments, the memory device further comprises a control circuit coupled to the bit line. The control circuit determines a logic value stored in the OTP NVM cell according to a current on the read path in the read operation.

In some embodiments, in the read operation, when the current has a small magnitude, the control circuit determines that the OTP NVM cell stores a low logic value, and when the current has a large magnitude, the control circuit determines that the OTP NVM cell stores a high logic value.

In some embodiments, in the write operation and the read operation, bulk voltages of the first transistor to the third transistor are equal to the ground voltage, and the source line has the ground voltage.

In some embodiments, in a read operation, when the OTP NVM cell stores a low logic value, the control terminal of the second transistor is floating, and when the OTP NVM cell stores a high logic value, the control terminal of the second transistor has a read bias.

In some embodiments, before a write operation to write a high logic value, the second terminal of the antifuse element is electrically disconnected from the program line, and in the write operation to write the high logic value, the first transistor is configured to turn on in response to the write word line having a first voltage, and the antifuse element is broke down in response to the program line having the first voltage to electrically connect the second terminal of the antifuse element to the program line.

In some embodiments, in a read operation before the write operation to write the high logic value, the OTP NVM cell stores a low logic value, and the control terminal of the second transistor is floating.

In some embodiments, in a read operation to read the high logic value, the control terminal of the second transistor has the first voltage.

Another aspect of the present disclosure is to provide an integrated circuit comprising a first transistor, a second transistor and an antifuse element. The first transistor comprises a first gate structure extending along a first direction. The second transistor comprises a first active area coupled to a source line and a second active area separated from the first active area along a second direction. The antifuse element comprising a third active area and a fourth active area connected to the third active area, wherein the third active area and the fourth active area have different conductive types and are coupled to the second active area and the first gate structure through a conductive segment.

In some embodiments, the integrated circuit further comprises a first well and a second well. The first well has a first conductive type. The first transistor is arranged on the first well. The second well is next to the first well along the first direction and has a second conductive type different from the first conductive type. The antifuse element is arranged on the second well.

In some embodiments, the antifuse element further comprises a second gate structure. In the first direction, a first side of the second gate structure is on a first shallow trench isolation structure, and a second side of the second gate structure is connected to the second well. The third active area has the first conductive type and is closer to the second gate structure compared with the fourth active area.

In some embodiments, the second active area and the fourth active area are separated by a second shallow trench isolation structure, and the third active area and the fourth active area are coupled to the conductive segment through a first via and a second via respectively.

In some embodiments, the integrated circuit further comprises a third transistor comprising a fifth active area coupled to the source line and a sixth active area shared with the first transistor. The third transistor and the first transistor are configured to form a read path.

In some embodiments, the first transistor further comprises a seventh active area configured to receive a bit line voltage in a read operation. In a write operation, the seventh active area is in a floating state.

In some embodiments, gate oxide layers of the first to third transistor have a first height. The first height is greater than a second height of a gate oxide layer of the antifuse element.

Another aspect of the present disclosure is to provide an operating method of the memory device, comprising: in a read operation, applying a first voltage to a first terminal of an antifuse element, in which a second terminal of the antifuse element is coupled to a control terminal of a first transistor; in the read operation, applying the first voltage to a control terminal of a second transistor to turn on the first transistor, in which a first terminal of the second transistor is coupled to a first terminal of the first transistor; and in the read operation, determining a logic value stored in the antifuse element according to a current in a bit line.

In some embodiments, the antifuse element stores a high logic value when the antifuse element has a low resistive state. The operating method further comprises: determining that the antifuse element stores the high logic value when the current is greater than a threshold value; and determining that the antifuse element stores a low logic value when the current is smaller than the threshold value.

In some embodiments, the operating method further comprises: in a write operation, applying a second voltage greater than the first voltage to a control terminal of a third transistor, in which a first terminal of the third transistor is coupled to the second terminal of the antifuse element; and in the write operation, applying the second voltage to the first terminal of the antifuse element to break down the antifuse element.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 depicts an example circuit diagram of a memory device in accordance with an embodiment.

FIG. 2 depicts an example circuit diagram corresponding to the OTP NVM cell in the memory device of FIG. 1 in accordance with an embodiment.

FIG. 3A depicts a schematic diagram of an integrated circuit configured with respect to the memory device of FIGS. 1-2 in a planar view in accordance with an embodiment.

FIG. 3B depicts a cross-section view of the integrated circuit corresponding to a line in FIG. 3A in accordance with an embodiment.

FIG. 4A depicts a schematic diagram of an integrated circuit 40 configured with respect to the memory device of FIGS. 1-2 in a planar view in accordance with an embodiment.

FIG. 4B depicts a cross-section view of a portion of the integrated circuit corresponding to a line in FIG. 4A in accordance with an embodiment.

FIG. 5 depicts a flowchart of a method of operating a memory device.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

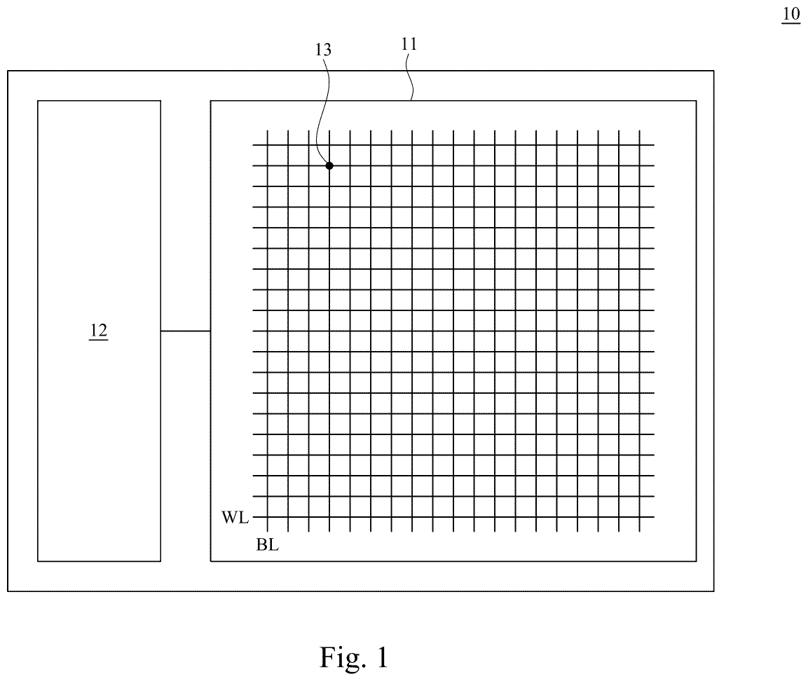

Reference is now made to FIG. 1. FIG. 1 depicts an example circuit diagram of a memory device 10 in accordance with an embodiment. For illustration, the memory device 10 includes a control circuit 12 and a memory array 11. The control circuit 12 is coupled to the memory array 11. The memory array 11 includes an one-time programmable non-volatile memory (OTP NVM) cell 13. According to some embodiments, The OTP NVM cell 13 is used for storage of data. The write (program) operation of the OTP NVM cell 13 is irreversible. In other words, the storage state of the OTP NVM cell 13 cannot be changed (or erased) after one write operation.

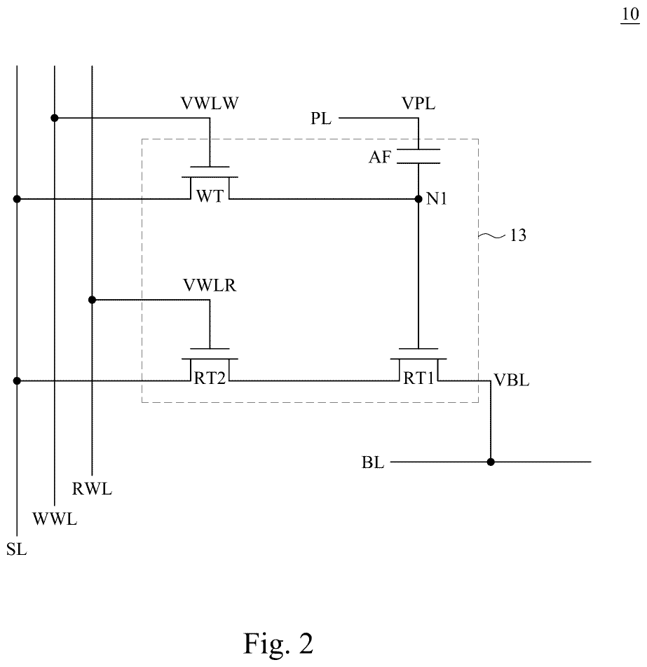

In some embodiments, the memory array 11 includes multiple OTP NVM cells 13 arranged in at least one row and at least one column, at least one word line WL and at least one bit line BL. Each word line WL is coupled to a corresponding row of the OTP NVM cells 13. Each bit line BL is coupled to a corresponding column of the OTP NVM cells 13. In some embodiments, each word line WL includes a write word line WWL and a read word line RWL (not shown in FIG. 1). Further details are described below with reference to FIG. 2.

In some embodiments, the control circuit 12 is coupled to the write word lines WWL, the read word lines RWL and the bit lines BL. According the some embodiments of the present disclosure, the control circuit 12 controls voltages on the word lines WL and the bit lines BL according to an address of an OTP NVM cell 13 to select the OTP NVM cell 13 to perform operations like write and read operations. For example, in a write operation to an OTP NVM cell 13, the control circuit 12 pulls high the voltage of a corresponding write word line WWL according to the row address of the OTP NVM cell 13, and pulls low the voltage of a corresponding bit line BL according to the column address of the OTP NVM cell 13 to select the OTP NVM cell 13 to perform the write operation.

Reference is now made to FIGS. 1-2. FIG. 2 depicts an example circuit diagram corresponding to the OTP NVM cell 13 in the memory device 10 of FIG. 1 in accordance with an embodiment. For illustration, the OTP NVM cell 13 includes an antifuse element AF, a transistor WT, a transistor RT1 and a transistor RT2.

In some embodiments, the resistance of the antifuse element AF defines the storage state (i.e., data, high logic value or low logic value) of the OTP NVM cell 13. The control circuit 12 performs a write operation to change the resistance of the antifuse element AF to write data to the OTP NVM cell 13. For example, the control circuit 12 applies a program voltage VPL to the antifuse element AF through a program line PL and breaks the antifuse element AF through a program current induced by the program voltage VPL, in which the dielectric (e.g., including silicon oxide, silicon nitride and silicon oxynitride, etc.) is broke down and the resistance of the antifuse element AF is changed. This operation is referred to as “programming” the antifuse element AF.

For example, when the OTP NVM cell 13 is not programmed yet, the dielectric of the antifuse element AF has high resistance. On the contrary, when the OTP NVM cell 13 is programmed in the write operation, the dielectric is broke down and has a storage state corresponding to low resistance. In some embodiments, the storage state of the antifuse element AF with the high resistance is a logic low state. On the contrary, the storage state of the antifuse element AF with the low resistance is a logic high state.

In some embodiments, the write path and the read path of the OTP NVM cell 13 are separated. For example, the transistor WT is turned on to form the write path of the antifuse element AF. The transistor RT1 and the transistor RT2 are configured as the read path.

In some embodiments, the antifuse element AF includes a metal-oxide-semiconductor (MOS) capacitor. The transistor RT1, the transistor RT2 and the transistor WT are n type metal-oxide-semiconductor field-effect transistors (NMOS).

As shown in FIG. 2, a first terminal of the antifuse element AF is coupled to a node N1. A second terminal of the antifuse element AF is coupled is coupled to the program line PL. The source/drain terminal of the transistor WT is coupled to the source line SL and the drain/source terminal of the transistor WT is coupled to the node N1. In other words, the first terminal of the antifuse element AF is coupled to the drain/source terminal of the transistor WT.

The control terminal (e.g., gate terminal) of the transistor WT is coupled to the write word line WWL to receive a write word line voltage VWLW when the OTP NVM cell 13 is selected to perform the write operation. The transistor WT is regarded as the select transistor of the write operation.

The control terminal (e.g., gate terminal) of the transistor RT1 is coupled to the node N1. In other words, the control terminal of the transistor RT1 is coupled to the first terminal of the antifuse element AF and the drain/source terminal of the transistor WT.

The drain/source terminal of the transistor RT1 is coupled to the bit line BL to receive a voltage VBL and the source/drain terminal of the transistor RT1 is coupled to the drain/source terminal of the transistor RT2. The source/drain terminal of the transistor RT2 is coupled to the source line SL to receive a source line voltage VSL. The control terminal (e.g., gate terminal) of the transistor RT2 is coupled to the read word line RWL to receive a read word line voltage VWLR when the OTP NVM cell 13 is selected to perform the read operation.

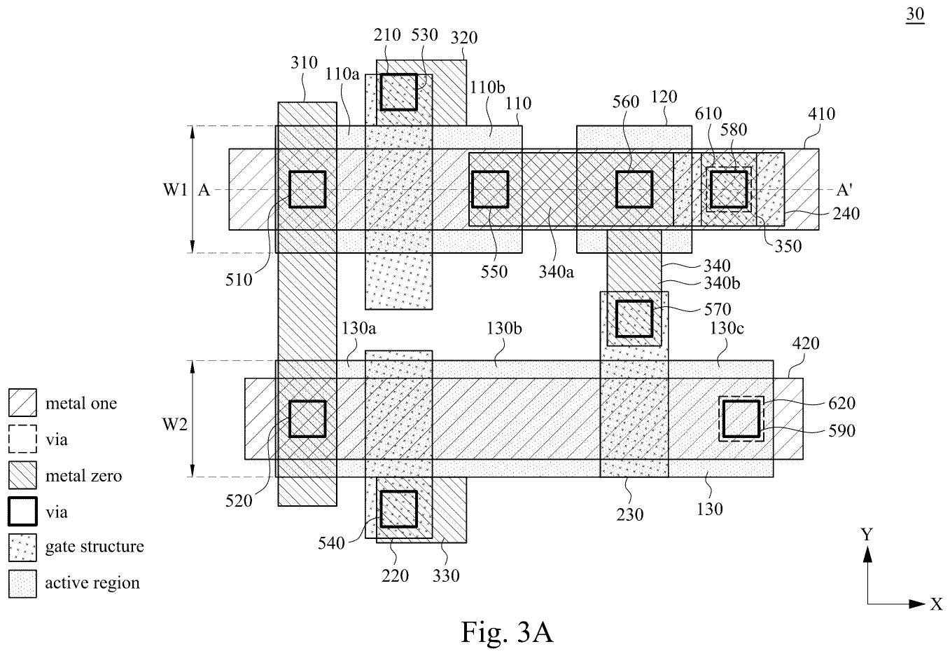

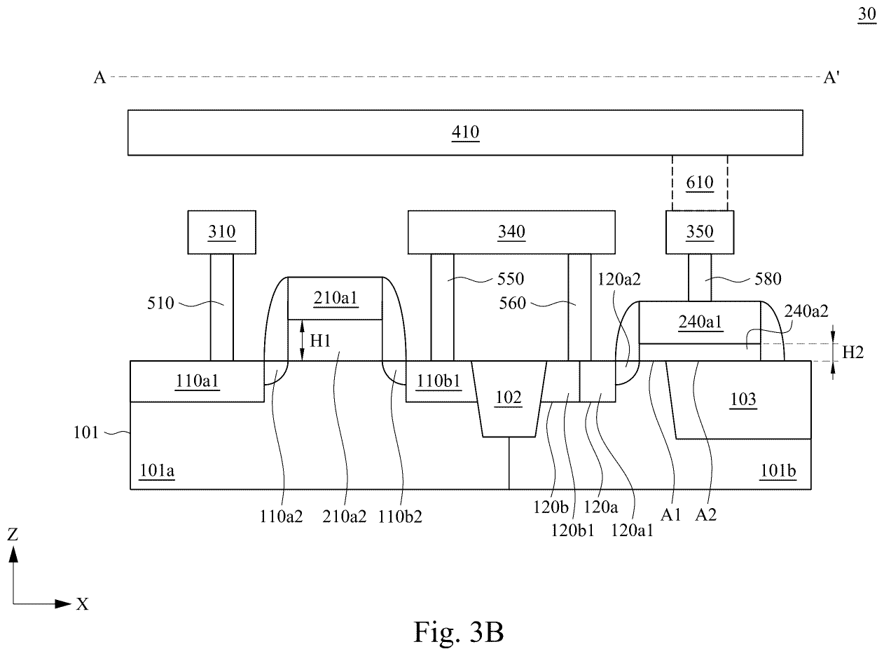

Reference is now made to FIGS. 1-2, 3A and 3B to describe the configurations and operations of the memory device 10. FIG. 3A depicts a schematic diagram of an integrated circuit 30 configured with respect to the memory device 10 of FIGS. 1-2 in a planar view in accordance with an embodiment. FIG. 3B depicts a cross-section view of the integrated circuit 30 corresponding to a line AA′ in FIG. 3A in accordance with an embodiment.

As shown in FIG. 3A, the integrated circuit 30 includes active regions 110-130, gate structures 210-240, conductive segments (metal-zero layer, MO) 310-350, conductive lines (metal-one layer, M1) 410-420, vias 510-590 and vias 610-620. In some embodiments, the active regions 110-130 are in a first semiconductor layer, the gate structures 210-240 are in a second semiconductor above the first semiconductor layer. The conductive segments 310-350 are in a third semiconductor above the second semiconductor layer. The vias 510-590 are conductive structures between the third semiconductor layer and the first or second semiconductor layers. The conductive lines 410-420 are in a fourth semiconductor layer above the third semiconductor layer. The vias 610-620 are conductive structures between the third and fourth semiconductor layers.

The active region 110 includes active areas 110a-110b and the active region 130 includes active areas 130a-130c. In some embodiments, the active area 110a corresponds to the source/drain terminal of the transistor WT. The active area 110b corresponds to the drain/source terminal of the transistor WT. The gate structure 210 corresponds to the control terminal of the transistor WT. The active area 130a and the gate structure 220 correspond to the source/drain terminal and the control terminal of the transistor RT2. The active region 130b corresponds to the drain/source terminal of the transistor RT2 and the source/drain terminal of the transistor RT1. The active area 130c corresponds to the drain/source terminal of the transistor RT1. The gate structure 230 corresponds to the control terminal of the transistor RT1.

The active region 110 and the active region 130 extend along a direction x and are separated from each other along the direction y. The gate structures 210-230 extend along the direction y. The gate structure 230 extends along the direction x and is separated from the gate structures 210-220. The gate structure 210 is separated from the gate structure 220 along the direction y. As shown in FIG. 3A, the gate structure 210 overlaps the active region 110 in the layout view. The gate structure 220 and the gate structure 230 overlap the active region 130. In the embodiments as shown in FIG. 3A, the active region 110 has a width W1 different from a width W2 of the active region 130. In some embodiments, the width W1 is greater than the width W2.

In some embodiments, along the direction x, the gate structure 240 is next to the active region 120. The active region 120 is between the gate structure 240 and the active region 110. The gate structure 240 and the active region 120 correspond to the terminal of the antifuse element AF coupled to the program line PL and the other terminal of the antifuse element AF coupled to the node N1.

The conductive segment 310 extends along the direction y and is coupled to the active areas 110a and 130a through the vias 510 and 520 respectively. The conductive segment 310 transmits the source line voltage VSL on the source line SL to the active area 110a and the active area 130a.

The conductive segments 320-330 extend along the direction x. The conductive segment 320 is coupled to the gate structure 210 through the via 530 to transmit the write word line voltage VWLW to the gate structure 210. The conductive segment 330 is coupled to the gate structure 220 through the via 540 to transmit the read word line voltage VWLR to the gate structure 220.

The conductive segment 340 includes a conductive segment 340a and a conductive segment 340b. The conductive segment 340a extends along the direction x and is coupled to the active area 110b and active region 120 through the vias 550 and 560. The conductive segment 340b extends along the direction y. The conductive segment 340b is coupled to the conductive segment 340a and coupled to the gate structure 230 through the via 570.

The conductive segment 350 is coupled between the via 580 and the via 610. The via 610 is further coupled to the conductive line 410.

The conductive lines 410 and 420 extend along the direction x. In some embodiments, the conductive line 410 is coupled to the gate structure 240 through the via 610, the conductive segment 350 and the via 580 to transmit the program voltage VPL. The conductive line 420 transmits the bit line voltage VBL through the vias 590 and 620 that coupled together to the active area 130c.

As shown in FIG. 3B, a substrate 101 includes a well 101a and a well 101b. The well 101a and the well 101b have different conductive types. In some embodiments, the well 101a is a p type well and the well 101b is an n type well. Along the direction x, the well 101a is next to the well 101b and the shallow trench isolation (STI) structure 102 is arranged between the well 101a and the well 101b.

The active area 110a is in the well 101a and includes a doped region 110a1 and a doped region 110a2. Similarly, the active area 110b is in the well 101a and includes a doped region 110b1 and a doped region 110b2. The active region 120 is in the well 101b. In some embodiments, the active region 110 and the active region 120 is separated by the STI structure 102.

The active region 120 includes the active area 120b and the active area 120a. The active area 120b and the active area 120a contact each other. The active area 120a includes a doped region 120a1, a low doped region 120a2. The active area 120b includes a doped region 120b1. In the direction x, the doped region 120a1 is next to the doped region 120b1. In the direction x, the doped region 120a1 is at a side closer to the gate structure 240 and the doped region 120b1 is in the other side further to the gate structure 240. The conductive type of the doped region 120b1 is different from the doped region 120a1 and the low doped region 120a2. In some embodiments, the doped region 120b1 is n type doped region. The doped region 120a1 is p type doped region. The low doped region 120a2 is p type low doped region. As shown in FIG. 3B, the doped region 120a1 and the doped region 120b1 are coupled to the via 560.

The gate structure 210 includes a gate electrode 210a1, gate oxide layer 210a2 and spacers at the two sides. Similarly, the gate structure 240 includes a gate electrode 240a1, the gate oxide layer 240a2 and spacers at the two sides. A portion of the gate structure 240 far from the active region 120 in the direction x is above the STI structure 103. A portion of the gate structure 240 close to the active region 120 in the direction x is above the well 101b. As shown in FIG. 3B, a portion A1 at the bottom of the gate oxide layer 240a2 contacts the well 101b. Another portion A2 at the bottom of the gate oxide layer 240a2 is separated from the well 101b by the STI structure 103.

Reference is now made to FIG. 3A to FIG. 3B. In some embodiments, the antifuse element AF at least includes the active region 120 and the gate structure 240. In some embodiments, in the write operation, the breakdown of the antifuse element AF occurs at the portion of the gate oxide layer 240a2 right above the portion A1 at the bottom.

In some embodiments, the antifuse element AF is a core device. The transistor RT1, the transistor RT2 and the transistor WT are input/output (I/O) devices. In this condition, the antifuse element AF has a thinner gate oxide layer, the transistors WT, RT1 and RT2 have thicker gate oxide layer. For example, the gate oxide layers (e.g., gate oxide layer 210a2) of the transistors RT1, RT2 and WT have a thickness H2 and the gate oxide layer 240a2 of the antifuse element AF has a thickness H2 smaller than the thickness H1. The antifuse element AF has higher tendency to be broke down than the transistors RT1, RT2 and WT.

Reference is now made to FIG. 1, 2, 3A and 3B for description of the write operation and the read operation. In some embodiments, voltages for performing the write operation and the read operation are shown in the following table 1.

TABLE 1
voltages for write operation and read operation

| | VWLW | VPL | VWLR | VBL | VSL | Vbulk |
|---|---|---|---|---|---|---|
| write | V1 | V1 | 0 | 0 | 0 | 0 |
| read | 0 | V2 | V2 | V3 | 0 | 0 |

The bulk voltage Vbulk is the bulk voltage (the voltage applied to the substrate 101 (well 101a and well 101b)) of the transistors RT1, RT2 and WT. In some embodiments, the voltages V1, V2 and V3 are different from each other. For example, the voltage V1 is greater than the voltage V2. The voltage V2 is greater than the voltage V3. In some embodiments, the voltage V1 is about 6 volts, the voltage V2 is about 1.6 volts and the voltage V3 is about 0.8 volts.

According to table 1, in the write operation, the write word line voltage VWLW is configured to the voltage V1 to turn on the transistor WT to form the write path from the program line PL to the source line SL and transmit the program voltage VPL that is configured to the voltage V1 to the antifuse element AF to break the dielectric layer of the antifuse element AF. In the write operation, the read word line voltage VWLR, the bit line voltage VBL, the source line voltage VSL and the bulk voltage Vbulk are configured to a ground voltage (e.g., 0 volts). In some embodiments, in the read operation, the bit line voltage VBL is floating instead of ground voltage to prevent the transistor RT1 from broke down.

For example, before the write operation to write the high logic value (e.g., logic one), the antifuse element AF has the high resistance to store the low logic value (e.g., logic zero). In other words, the terminal, of the antifuse element AF, corresponding to the active region 120 is electrically disconnected from the conductive line 410 corresponding to program line PL. Then, in the write operation, the transistor WT is turned on in response to the write word line voltage VWLW. The gate structure 240 of the antifuse element AF receives the program voltage VPL. The antifuse element AF is broke down in response to the program voltage VPL to make the active region 120 coupled to the conductive line 410 corresponding to the program line PL through the well 101b, the gate structure 240, the via 580, the conductive segment 350 and the via 610. As a result, the antifuse element AF is changed to have the low resistance that corresponds to storage of the high logic value.

In the read operation, the read word line voltage VWLR is configured to the voltage V2 to turn on the transistor RT2. The bit line voltage VBL is configured to the voltage V3. The write word line voltage VWLW, the source line voltage VSL and the bulk voltage Vbulk are configured to the ground voltage. Under such configurations, the voltage level of the control terminal of the transistor RT1 is related to the voltage level of the terminal of the antifuse element AF.

For example, in the read operation to the OTP NVM cell 13 that changed to store the high logic value as described in the above embodiment, because the dielectric layer (gate oxide layer 240a2) of the antifuse element AF is broke down, the antifuse element AF has the low resistance corresponding to the high logic value. The program line PL and the active region 120 are turned on to set the voltage of the control terminal of the transistor RT1 to a read bias related to the program voltage VPL. In some embodiments, the read bias is equal to or smaller than the program voltage VPL. Accordingly, the transistor RT1 and the transistor RT2 are turned on to make the bit line electrically connected to the source line SL. The control circuit 12 determines that the storage state of the antifuse element AF is the high logic value according to a current on the bit line BL (i.e., the current on the conductive path formed by the transistor RT1 and the transistor RT2).

On the contrary, when the dielectric layer (gate oxide layer 240a2) of the antifuse element AF is not broke down (i.e., the antifuse element AF has the high resistance corresponding to the low logic value), the gate structure 230 is floating. In other words, the control terminal of the transistor RT1 in the read operation of reading the low logic value is floating to make the transistor RT1 turned off. Then, the control circuit 12 determines that the storage state of the antifuse element AF is the low logic value according to the current on the bit line BL.

In some embodiments, the control circuit 12 determines that the storage state of the OTP NVM cell 13 is the high logic value according to the current on the bit line BL having a high current value. The control circuit 12 determines that the storage state of the OTP NVM cell 13 is the low logic value according to the current on the bit line BL having a low current value.

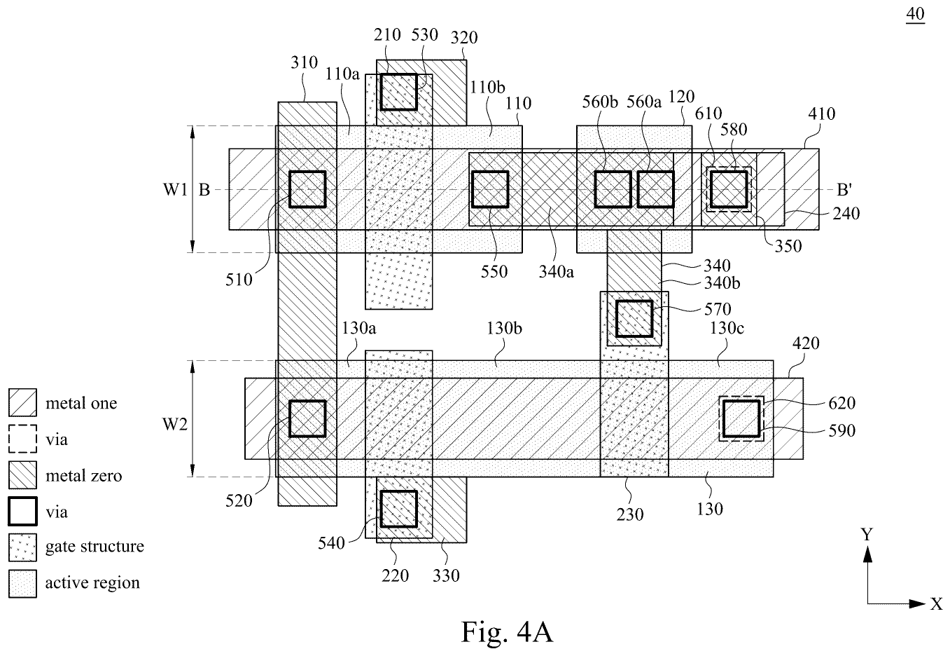

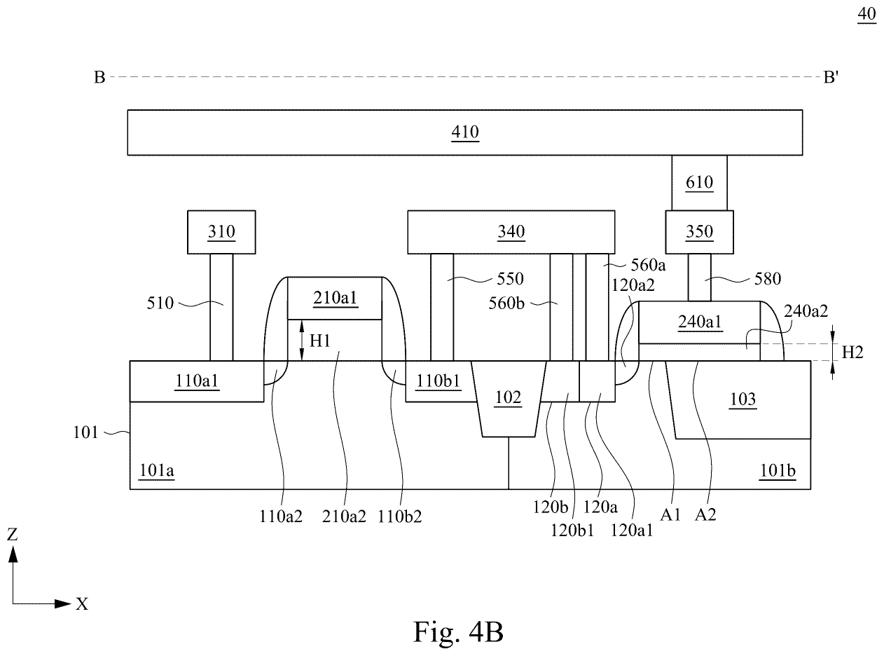

Reference is now made to FIGS. 4A to 4B. FIG. 4A depicts a schematic diagram of an integrated circuit 40 configured with respect to the memory device 10 of FIGS. 1-2 in a planar view in accordance with an embodiment. FIG. 4B depicts a cross-section view of a portion of the integrated circuit 40 corresponding to a line BB′ in FIG. 4A in accordance with an embodiment.

Compared with the integrated circuit 30 of FIGS. 3A-3B, the integrated circuit 40 of FIGS. 4A-4B does not include the via 560, the doped regions 120a1 and 120b1 are coupled to the conductive segment 340 through the vias 560a and 560b respectively.

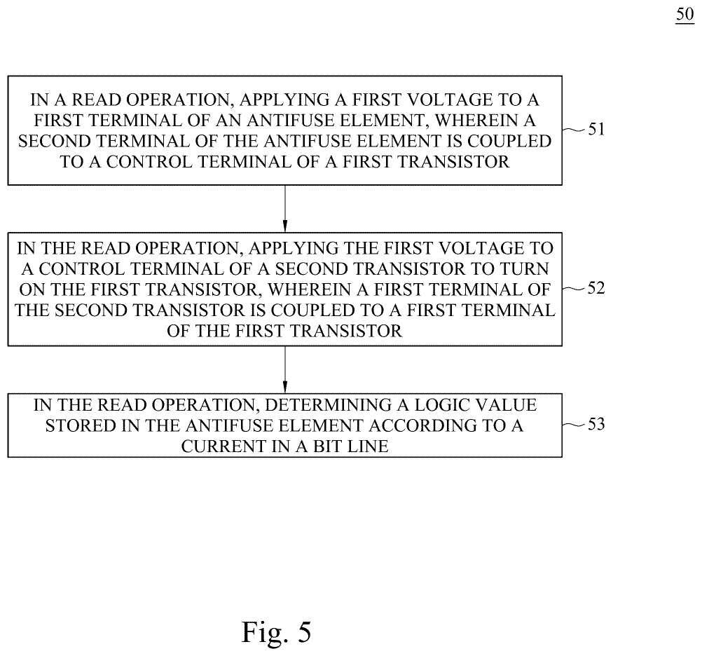

Reference is now made to FIG. 5. FIG. 5 depicts a flowchart of a method 50 of operating a memory device. It is understood that additional steps can be provided before, during, and after the processes shown by FIG. 5, and some of the steps described below can be replaced or eliminated, for additional embodiments of the method 50. The method 50 includes steps 51-53. The method 50 of operating the memory device would be discussed below in coordination with the embodiments of FIGS. 1-2, 3A-3B and 4A-4B.

In step 51, in the read operation to the OTP NVM cell 13, the voltage V2 is applied to the terminal of the antifuse element AF through the program line PL. The other terminal of the antifuse element AF is coupled to the control terminal of the transistor RT1.

In step 52, in the read operation to the OTP NVM cell 13, the voltage V2 is applied to the control terminal of the transistor RT2 through the read word line RWL to turn on the transistor RT1 and RT2. The other terminal of the antifuse element AF is coupled to the control terminal of the transistor RT1.

In some embodiments, step 51 and step 52 are performed simultaneously.

In step 53, in the read operation to the OTP NVM cell 13, the logic value stored in the antifuse element AF is determined according to the current on the bit line BL.

In some embodiments, the method 50 for operating the memory device further includes the following step: determining that the storage state of the OTP NVM cell 13 is the high logic value according to the current on the bit line BL greater than a threshold value; and determining that the storage state of the OTP NVM cell 13 is the low logic value according to the current on the bit line BL smaller than the threshold value.

In some embodiments, the method 50 for operating the memory device further includes the following step: in the write operation to the OTP NVM cell 13, making the bit line BL be floating; applying the voltage V1 to the control terminal of the transistor WT, in which the source/drain terminal of the transistor WT is coupled to a terminal (node N1) of the antifuse element AF; and applying the voltage V1 to the terminal, coupled to the program line PL, of the antifuse element AF to make the antifuse element AF broke down. In some embodiments, the voltage V1 is applied to the control terminal of the transistor WT and the terminal, coupled to the program line PL, of the antifuse element AF.

In summary, the memory device, the integrated circuit and the method of operating the memory device provides an OTP NVM cell in which the read path and the write path are separated from each other. With such configuration, great difference of read currents between individual memory devices caused by the difference of severity of dielectric breakdown is prevented. Therefore, the consistence of the red currents are ensured, which helps lower error rate and reduce usage of extra circuits (e.g., error correction code circuit) for correction to improve the performance of the memory device.

While the disclosure has been described by way of example(s) and in terms of the preferred embodiment(s), it is to be understood that the disclosure is not limited thereto. Those skilled in the art may make various changes, substitutions, and alterations herein without departing from the spirit and scope of the present disclosure. In view of the foregoing, it is intended that the present invention cover modifications and variations of this invention provided they fall within the scope of the following claims.

What is claimed is:

1. A memory device, comprising a one-time programmable non-volatile memory (OTP NVM) cell that comprises:
an antifuse element having a first terminal coupled to a program line;
a first transistor coupled between a second terminal of the antifuse element and a source line, wherein the first transistor is configured to be turned on to form a write path to the antifuse element;
a second transistor, wherein a control terminal of the second transistor is coupled to the second terminal of the antifuse element; and
a third transistor configured to be turned on to form a read path to the antifuse element, wherein a first terminal of the third transistor is coupled to the source line and a second terminal of the third transistor is coupled to a first terminal of the second transistor.

2. The memory device of claim 1, wherein a control terminal of the first transistor is coupled to a write word line, a second terminal of the second transistor is coupled to a bit line and a control terminal of the third transistor is coupled to a read word line,
wherein in a write operation, the write word line and the program line have a first voltage, and the read word line and the bit line have a ground voltage.

3. The memory device of claim 2, wherein in a read operation, the write word line has the ground voltage, the program line and the read word line have a second voltage smaller than the first voltage, and the bit line has a third voltage smaller than the second voltage.

4. The memory device of claim 3, further comprising:
a control circuit coupled to the bit line, wherein the control circuit is configured to determine a logic value stored in the OTP NVM cell according to a current on the read path in the read operation.

5. The memory device of claim 4, wherein in the read operation, when the current has a small magnitude, the control circuit determines that the OTP NVM cell stores a low logic value, and
when the current has a large magnitude, the control circuit determines that the OTP NVM cell stores a high logic value.

6. The memory device of claim 3, wherein in the write operation and the read operation, bulk voltages of the first transistor to the third transistor are equal to the ground voltage, and the source line has the ground voltage.

7. The memory device of claim 1, wherein in a read operation, when the OTP NVM cell stores a low logic value, the control terminal of the second transistor is floating, and
when the OTP NVM cell stores a high logic value, the control terminal of the second transistor has a read bias.

8. The memory device of claim 1, wherein before a write operation to write a high logic value, the second terminal of the antifuse element is electrically disconnected from the program line,
in the write operation to write the high logic value, the first transistor is configured to turn on in response to a write word line having a first voltage, and the antifuse element is broke down in response to the program line having the first voltage to electrically connect the second terminal of the antifuse element to the program line.

9. The memory device of claim 8, wherein in a read operation before the write operation to write the high logic value, the OTP NVM cell stores a low logic value, and the control terminal of the second transistor is floating.

10. The memory device of claim 8, wherein in a read operation to read the high logic value, the control terminal of the second transistor has the first voltage.

11. An integrated circuit, comprising:
a first transistor comprising a first gate structure extending along a first direction;
a second transistor comprising a first active area coupled to a source line and a second active area separated from the first active area along a second direction; and
an antifuse element comprising a third active area and a fourth active area connected to the third active area,
wherein the third active area and the fourth active area have different conductive types and are coupled to the second active area and the first gate structure through a conductive segment.

12. The integrated circuit of claim 11, further comprising:
a first well having a first conductive type, wherein the first transistor is arranged on the first well; and
a second well that is next to the first well along the first direction and has a second conductive type different from the first conductive type, wherein the antifuse element is arranged on the second well.

13. The integrated circuit of claim 12, wherein the antifuse element further comprises:
a second gate structure, wherein in the first direction, a first side of the second gate structure is on a first shallow trench isolation structure, and a second side of the second gate structure is connected to the second well,
wherein the third active area has the first conductive type and is closer to the second gate structure compared with the fourth active area.

14. The integrated circuit of claim 13, wherein the second active area and the fourth active area are separated by a second shallow trench isolation structure, and
the third active area and the fourth active area are coupled to the conductive segment through a first via and a second via respectively.

15. The integrated circuit of claim 11, further comprising:
a third transistor comprising a fifth active area coupled to the source line and a sixth active area shared with the first transistor, wherein the third transistor and the first transistor are configured to form a read path.

16. The integrated circuit of claim 15, wherein the first transistor further comprises:
a seventh active area configured to receive a bit line voltage in a read operation, wherein in a write operation, the seventh active area is in a floating state.

17. The integrated circuit of claim 15, wherein gate oxide layers of the first to third transistor have a first height,
wherein the first height is greater than a second height of a gate oxide layer of the antifuse element.

18. An operating method of memory device, comprising:
in a read operation, applying a first voltage to a first terminal of an antifuse element, wherein a second terminal of the antifuse element is coupled to a control terminal of a first transistor;
in the read operation, applying the first voltage to a control terminal of a second transistor to turn on the first transistor, wherein a first terminal of the second transistor is coupled to a first terminal of the first transistor; and
in the read operation, determining a logic value stored in the antifuse element according to a current in a bit line.

19. The operating method of claim 18, wherein the antifuse element stores a high logic value when the antifuse element has a low resistive state,
wherein the operating method further comprises:
determining that the antifuse element stores the high logic value when the current is greater than a threshold value; and
determining that the antifuse element stores a low logic value when the current is smaller than the threshold value.

20. The operating method of claim 18, further comprising:
in a write operation, applying a second voltage greater than the first voltage to a control terminal of a third transistor, wherein a first terminal of the third transistor is coupled to the second terminal of the antifuse element; and
in the write operation, applying the second voltage to the first terminal of the antifuse element to break down the antifuse element.
